(19) United States
(12) Patent Application Publication
(10) Pub. No.: US 2001/0020723 A1
(43) Pub. Date: Sep. 13, 2001

(54) TRANSISTOR HAVING A TRANSITION METAL OXIDE GATE DIELECTRIC AND METHOD OF MAKING SAME

(76) Inventors: MARK I. GARDNER, CEDAR CREEK, TX (US); DERRICK J. WRISTERS, AUSTIN, TX (US); DANIEL KADOSH, AUSTIN, TX (US)

Correspondence Address: KEVIN L DAFFER, CONLEY ROSE & TAYON, P O BOX 398, AUSTIN, TX, 787670398

(21) Appl. No.: 09/111,054

(22) Filed: Jul. 7, 1998

(51) Int. Cl. H01L 31/119; H01L 31/113; H01L 29/76; H01L 29/94

(52) U.S. Cl. 257/368

(57) ABSTRACT

An integrated circuit and process for making the same is provided in which a transistor including a gate dielectric and a gate conductor is formed upon a semiconductor substrate. Preferably, the gate dielectric has a dielectric constant greater than the dielectric constant of silicon dioxide. In an embodiment, the gate dielectric is formed from a transition metal oxide. Preferably, the transition metal oxide is formed by oxidation of a transition metal spacer. The transition metal spacer may be reduced, prior to oxidation such that a later extent of the spacer is substantially less than a lateral extent of the gate conductor.

### BACKGROUND OF THE INVENTION

1. Field of the Invention

This invention relates to integrated circuit fabrication and, more particularly, to forming a transistor having a transition metal oxide gate dielectric.

2. Description of the Relevant Art

Fabrication of a MOSFET device is well known. Generally speaking, MOSFETs are manufactured by placing an undoped polycrystalline (“polysilicon”) material over a relatively thin gate oxide. The polysilicon material and the gate oxide are then patterned to form a gate conductor with source/drain regions adjacent to and on opposite sides of the gate conductor. The gate conductor and source/drain regions are then implanted with an impurity dopant species. If the impurity dopant species used for forming the source/drain regions is n-type, then the resulting MOSFET is an NMOSFET (“n-channel”) transistor device. Conversely, if the source/drain dopant species is p-type, then the resulting MOSFET is a PMOSFET (“p-channel”) transistor device. Integrated circuits utilize either n-channel devices exclusively, p-channel devices exclusively, or a combination of both on a single substrate. While both types of devices can be formed, the devices are distinguishable based on the dopant species used.

Because of the increased desire to build faster and more complex integrated circuits, it has become necessary to reduce the transistor threshold voltage, V_{T}, while the transistor is in its on state. Several factors contribute to V_{T}, one of which is the gate-to-substrate capacitance. The higher the gate-to-substrate capacitance, the lower the V_{T} of a transistor. The value of this capacitance is dependent upon the thickness of the gate oxide, and the relative permittivity of the gate oxide. Unfortunately, the relative permittivity, or dielectric constant, K, of the gate oxide limits the amount of gate-to-substrate capacitance that can be achieved when a transistor is in operation. Permittivity, ε, of a material reflects the ability of the material to be polarized by an electric field. The capacitance between two layers of conductive material separated by a dielectric is directly proportional to the permittivity of the dielectric. The permittivity of a material is typically described as its permittivity normalized to the permittivity of a vacuum, εₒ. Hence, the relative permittivity or dielectric constant of a material is defined as:

K=ε/εₒ

Since oxide (i.e., silicon dioxide) has a relatively low K of approximately 3.7 to 3.8, the minimum value of V_{T}, and thus the transistor switching speed, must be somewhat sacrificed in order to promote capacitive coupling between the gate conductor and the substrate.

As mentioned above, the gate-to-substrate capacitance is also affected by the thickness of the gate oxide. Conventional transistors typically include an ultra thin gate oxide to reduce the gate-to-substrate capacitance, and thereby lower V_{T}. The value of the gate-to-source voltage, V_{GS}, required to invert the channel underneath the gate conductor such that a drive current, I_{D}, flows between the source and drain regions of the transistor is decreased. Consequently, the switching speed (from off to on and vice versa) of the logic gates of an integrated circuit employing such transistors is faster, allowing the integrated circuit to quickly transition between logic states (i.e., operate at high frequencies).

Unfortunately, thin oxide films may break down when subjected to an electric field. Particularly, for a gate oxide which is less than 50 Å thick, it is probable that when V_{GS} is equivalent to only 3V, electrons can pass through the gate oxide by what is known as the quantum mechanical tunneling effect. In this manner, a tunneling current may undesirably form between the semiconductor substrate and the gate conductor, adversely affecting the operability of the device. It is postulated that these electrons may become entrapped within the gate oxide by e.g., dangling bonds. As a result, a net negative charge density may form in the gate oxide. As the trapped charge accumulates with time, V_{T} may shift from its design specification. Breakdown of the gate oxide may also occur at even lower values of V_{GS}, as a result of defects in the gate oxide. Such defects are unfortunately prevalent in relatively thin gate oxides. For example, a thin gate oxide often contains pinholes and/or localized voids due to unevenness at which the oxide grows on a less than perfect silicon lattice. Low breakdown voltages also correlate with high defect density near the surface of the substrate.

It would therefore be desirable to develop a technique for fabricating a transistor with reduced gate-to-substrate capacitance which is substantially resistant to gate dielectric breakdown. Fabrication of a relatively thin gate oxide interposed between the gate and the substrate must be avoided. A transistor with the immediately preceding advantages must also switch on and off quickly, thereby providing for high frequency operation of an integrated circuit. Further, formation of a tunneling current between the gate dielectric and the gate conductor of the resulting transistor would be less likely. The possibility of electrons becoming trapped within the gate dielectric would also be reduced. The transistor would thus be substantially resistant to threshold skews from the desired value of V_{T}.

In addition to control of the properties of the gate oxide, another factor which influences V_{T} is the effective channel length (“Leff”) of the transistor. The initial distance between the source-side junction and the drain-side junction of a transistor is often referred to as the physical channel length. However, after implantation and subsequent diffusion of the junctions, the actual distance between junctions becomes less than the physical channel length and is often referred to as the effective channel length. In VLSI designs, as the physical channel length decreases, so too must the Leff. Decreasing Leff reduces the distance between the depletion regions associated with the source and drain of a transistor. As a result, less gate charge is required to invert the channel of a transistor having a shorter Leff. Accordingly, reducing the physical channel length, and hence the Leff, can lead to a reduction in the threshold voltage of a transistor. Consequently, the switching speed of the logic gates of an integrated circuit employing transistors with reduced Leff is faster, allowing the integrated circuit to quickly transition between logic states (i.e., operate at high frequencies).

Unfortunately, minimizing the physical channel length of a transistor is somewhat limited by conventional techniques used to define the gate conductor of the transistor. As mentioned earlier, the gate conductor is typically formed from a polysilicon material. A technique known as lithography is used to pattern a photosensitive film (i.e., photoresist) above the polysilicon material. An optical image is transferred to the photoresist by projecting a form of radiation, typically ultraviolet light, through the transparent portions of a mask plate. The solubility of photoresist regions exposed to the radiation is altered by a photochemical reaction. The photoresist is washed with a solvent that preferentially removes resist areas of higher solubility. Those exposed portions of the polysilicon material not protected by photoresist are etched away, defining the geometric shape of a polysilicon gate conductor.

The lateral width (i.e., the distance between opposed sidewall surfaces) of the gate conductor which dictates the physical channel length of a transistor is thus defined by the lateral width of an overlying photoresist layer. The minimum lateral dimension that can be achieved for a patterned photoresist layer is unfortunately limited by, inter alia, the resolution of the optical system (i.e., aligner or printer) used to project the image onto the photoresist. The term “resolution” describes the ability of an optical system to distinguish closely spaced objects. Diffraction effects may undesirably occur as the radiation passes through slit-like transparent regions of the mask plate, scattering the radiation and therefore adversely affecting the resolution of the optical system. As such, the features patterned upon a masking plate may be skewed, enlarged, shortened, or otherwise incorrectly printed onto the photoresist.

It would therefore be desirable to develop a transistor fabrication technique in which the channel length of the transistor is reduced to provide for high frequency operation of an integrated circuit employing the transistor. More specifically, a process is needed in which the channel length is no longer dictated by the resolution of a lithography optical aligner, or dual sides of a masking structure. Thus, the Leff of a transistor must no longer be mandated by the lateral width of a lithographically patterned gate conductor.

### SUMMARY OF INVENTION

The problems outlined above are in large part solved by the technique hereof for fabricating a transistor in which the channel length is mandated by the lateral width of a gate dielectric having a dielectric constant, K, greater than about 3.8 (i.e., greater than the K value of silicon dioxide). The high K value of the gate dielectric advantageously allows the vertical thickness of the gate dielectric to be increased without being concerned that gate-to-substrate capacitance will be lost. In other words, the thickness of the gate dielectric can be increased and still achieve the same transistor threshold voltage V_{T} as a gate dielectric composed of a material having a lower K value, e.g., silicon dioxide. Accordingly, the thickness of the gate dielectric may be made sufficiently large to serve as a mask during subsequent implantation of impurities into a semiconductor substrate which extends beneath and horizontally beyond the gate dielectric. Finally, the lateral extent of the gate dielectric may be used to define the channel length. By minimizing the lateral extent of the gate dielectric, the channel length may also be reduced below a channel length that would be obtainable via photolithography.

A variety of materials may be used as the gate dielectric which have a high K value. In the present invention, transition metal oxides may be used as a high K material. Typically, transition metal oxides have a K value of between about 20-30, compared to the relatively low K value of silicon dioxide (3.8). Examples of transition metal oxides which may be used include titanium dioxide (TiO₂), tantalum pentoxide (Ta₂O₅), and zirconium oxide (ZrO₂). Typically, the deposition and etching of transition metal oxides may be difficult under standard semiconductor processing conditions. The deposition and etching of the corresponding metals (e.g., titanium, tantalum, and zirconium), however, may be readily accomplished during normal semiconductor processing. The present invention thus relates to the formation of transition metal oxide dielectrics by forming a transition metal dielectric layer and subsequently oxidizing the transition metal to the corresponding transition metal oxide. In this manner, the difficulties in handling transition metal oxides may be avoided.

In one embodiment, a series of layers are formed upon a semiconductor substrate. A barrier layer is formed upon the semiconductor substrate. The barrier layer is preferably composed of silicon nitride or a silicon oxynitride/silicon nitride stack. It is desired to create a transistor having a high K material between the gate conductor and the substrate. Thus it is important that all of the material which lie between the gate conductor and the substrate have relatively high K values. It is thus preferred that silicon nitride, silicon oxynitride, or a silicon oxynitride/silicon nitride stack is used as the barrier layer rather than silicon oxide. Both silicon oxynitride and silicon nitride have significantly higher dielectric constants, K, than silicon oxide. The use of silicon dioxide in place of silicon nitride may make it difficult to increase the gate conductor-to-substrate distance to a sufficient distance to reduce gate dielectric breakdown.

Upon the barrier layer, a transition metal layer is formed, followed by a gate conductor layer. Finally, a masking layer is formed upon the gate conductor layer. The masking layer may have a width no less than the minimum lateral dimension definable by lithography. Portions of the gate conductor and the underlying transition metal layer not covered by the masking layer are then etched to the underlying substrate. As a result, the gate conductor and the transition metal spacer each have a lateral width equivalent to that of the masking layer.

To reduce the channel length of the transistor, the transition layer spacer may be further reduced by a subsequent wet etch process. This process may be continued until the desired channel length is obtained. The reduction of the lateral extent of the transition metal layer allows the formation of a transistor having a channel length which may be less than the optical resolution of the photolithographic equipment. For example, if the masking layer is initially formed at the optical resolution limit of the photolithographic equipment, the subsequent reduction of the width of the transition metal layer preferably allows the channel region of the gate conductor to be formed having a lateral width below the optical resolution of the photolithographic equipment. An advantage of this process is that the density of transistors in an integrated circuit may be increased by using these reduced-width transistors. Another advantage is that the gate conductor may be substantially centered upon the transition metal layer, thus avoiding alignment problems which may occur if the gate conductor is formed after formation of the transition metal layer.

After removal of the exposed layers, oxidation of the transition metal spacer is performed to convert substantially all of the transition metal spacer to a transition metal oxide spacer. Oxidation is performed when the transition metal spacer is heated in, e.g., a oxygen (O₂), nitric oxide (NO), or nitrous oxide (N₂O) atmosphere. As a result of being subjected to a heat cycle in an oxygen containing atmosphere, the transition metal spacer is oxidized to form a transition metal oxide spacer. During oxidation of transition metal spacer, a portion of the transition metal spacer may react with the gate conductor to form a silicide layer. The formed silicide layer, in combination with the polysilicon gate conductor, may together serve as the gate conductor structure. Alternatively, the gate conductor may be composed of cobalt or tungsten. Use of cobalt or tungsten would prevent formation of silicide between the gate conductor and the semiconductor substrate.

The barrier layer, positioned under the transition metal layer, is used to inhibit formation of silicide between the transition metal spacer and the semiconductor substrate. The absence of such a barrier layer may allow the formation of silicide layer between the transition metal spacer and the substrate during oxidation of the spacer. A silicide layer in this position may reduce the gate-to-substrate capacitance causing the transistor to become ineffective.

Additionally, oxidation of the transition metal spacer may also cause portions of the gate conductor to become partially oxidized, when the gate conductor is composed of polysilicon. Outer portions, which are not covered by the masking layer, may be converted to silicon dioxide or silicon oxynitride during the oxidation process, depending on the conditions used. The central portion of the gate conductor preferably remains unoxidized, (i.e., is composed of polysilicon). The masking layer preferably prevents the oxidation of an upper portion of the gate conductor. Thus, the height of the unoxidized portion of gate conductor remains substantially unchanged.

Subsequently, a first dopant distribution is implanted into the semiconductor substrate. The semiconductor substrate is treated with a gaseous first dopant source to form LDD areas adjacent to the transition metal oxide spacer. The use of a gaseous dopant species, rather than an ion implantation process, allows the implantation to enter portions of the semiconductor substrate directly under the oxidized gate conductor portions, which may overhang the transition metal spacer. Further processing includes the formation of source/drain regions and salicide regions to complete the transistor.

In another embodiment, the formation of the gate conductor layer is preferably performed such that gate conductor has a width substantially greater than a width of the gate conductor formed in the previous embodiments. The gate conductor may have a height substantially greater than a height of the transition metal spacer. After etching of the layers, the masking layer is removed, preferably exposing the upper surface of the gate conductor.

Subsequent oxidation of the transition metal spacer also causes concurrent oxidation of the exposed portions of gate conductor, when the gate conductor is composed of polysilicon. An outer portion of the gate conductor may be converted to silicon dioxide or silicon oxynitride during the oxidation process, depending on the conditions used. The central portion of gate conductor preferably remains unoxidized, (i.e., is composed of polysilicon). Typically, the oxidation of the transition metal spacer occurs at a substantially faster rate than the oxidation of the gate conductor. To ensure that the oxidation of the transition metal spacer may be substantially completed before the gate conductor is oxidized, the gate conductor is formed having a height sufficient to inhibit complete oxidation of the gate conductor during the time period required to oxidize substantially all of the transition metal spacer. Thus, oxidation of the gate conductor forms a layer of dielectric material surrounding the gate conductor along the sidewalls and the upper surface of the gate conductor. An advantage of this process is that the formation of an interlevel dielectric by an additional processing step may be avoided.

In another embodiment, a series of layers are formed upon a semiconductor substrate. A first barrier layer is formed upon the semiconductor layer. Barrier layer is preferably composed of silicon nitride or a silicon oxynitride/silicon nitride stack. Upon the barrier layer a transition metal layer is formed, followed by a second barrier layer. Upon the second barrier layer a gate conductor layer is formed. Finally, a masking layer is formed upon the gate conductor layer. Portions of the gate conductor, the second barrier layer, and the underlying transition metal layer not covered by the masking layer are then etched to the underlying substrate.

After etching, the transition metal substrate is oxidized to a transition metal oxide substrate. In the previous embodiments, oxidation of the transition metal spacer causes a portion of the transition metal spacer to react with the gate conductor to form a silicide layer. In the current embodiment, the second barrier layer inhibits the formation of a silicide layer between the transition metal oxide spacer and the gate conductor. When a silicide layer is formed between the gate conductor and the transition metal oxide spacer, the height of the oxide spacer required to produced the desired gate-to-substrate capacitance must be increased, since the silicide increases the overall conductivity of the gate conductor. By preventing the formation of a silicide the oxide spacer layer height may be optimized such that the feature height of the transistor may be minimized, through use of a minimal amount of transition metal oxide, while sufficient distance between the gate conductor and the substrate exists to reduce gate dielectric breakdown.

### BRIEF DESCRIPTION OF THE DRAWINGS

Other objects and advantages of the invention will become apparent upon reading the following detailed description and upon reference to the accompanying drawings in which:

FIG. 1a is a partial cross-sectional view of a semiconductor substrate upon which a barrier layer, a transition metal layer, a gate conductor layer and a masking layer are formed;

FIG. 1b is a detailed view of the barrier layer of FIG. 1a showing the two layers of the barrier layer;

FIG. 2 is a processing step subsequent to FIG. 1, in which the masking layer is patterned and the exposed portions of the gate conductor layer, and the transition metal layer are removed;

FIG. 3 is a processing step subsequent to FIG. 2, in which a lateral extent of the transition metal spacer is reduced;

FIG. 4 is a processing step subsequent to FIG. 3, in which the transition metal spacer is oxidized to a transition metal oxide spacer;

FIG. 5 is a processing step subsequent to FIG. 4, in which a first dopant distribution is forwarded into the semiconductor substrate;

FIG. 6 is a processing step subsequent to FIG. 5, in which a second dopant distribution is forwarded into the semiconductor substrate;

FIG. 7 is a processing step subsequent to FIG. 6, in which salicide layers are formed;

FIG. 8 is a processing step subsequent to FIG. 5, in which spacer structures are formed adjacent to the gate conductor;

FIG. 9 is a processing step subsequent to FIG. 8, in which a second dopant distribution is forwarded into the semiconductor substrate;

FIG. 10 is a processing step subsequent to FIG. 9, in which salicide layers are formed;

FIG. 11 is a partial cross-sectional view of a semiconductor substrate upon which a barrier layer, a transition metal spacer, and a gate conductor are formed;

FIG. 12 is a processing step subsequent to FIG. 11, in which the transition metal spacer is oxidized to form a transition metal oxide spacer;

FIG. 13 is a processing step subsequent to FIG. 12, in which spacer structures, first dopant distribution areas and second dopant distribution areas are formed;

FIG. 14 is a partial cross-sectional view of a semiconductor substrate upon which a first barrier layer, a transition metal spacer, a second barrier layer, a gate conductor, and a masking layer are formed;

FIG. 15 is a processing step subsequent to FIG. 14, in which the masking layer is patterned and the exposed portions of the gate conductor layer, the second barrier layer, and the transition metal layer are removed;

FIG. 16 is a processing step subsequent to FIG. 15, in which the lateral extent of the transition metal spacer is reduced;

FIG. 17 is a processing step subsequent to FIG. 16, in which the transition metal spacer is oxidized to a transition metal oxide spacer;

FIG. 18 is a processing step subsequent to FIG. 17, in which a first dopant distribution is forwarded into the semiconductor substrate;

FIG. 19 is a processing step subsequent to FIG. 18, in which a second dopant distribution is forwarded into the semiconductor substrate and salicide layers are formed.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but, on the contrary, the intention is to cover all modifications, equivalents, and alternatives falling within the spirit and scope of the present invention as defined by the appended claims.

### DETAILED DESCRIPTION OF THE INVENTION

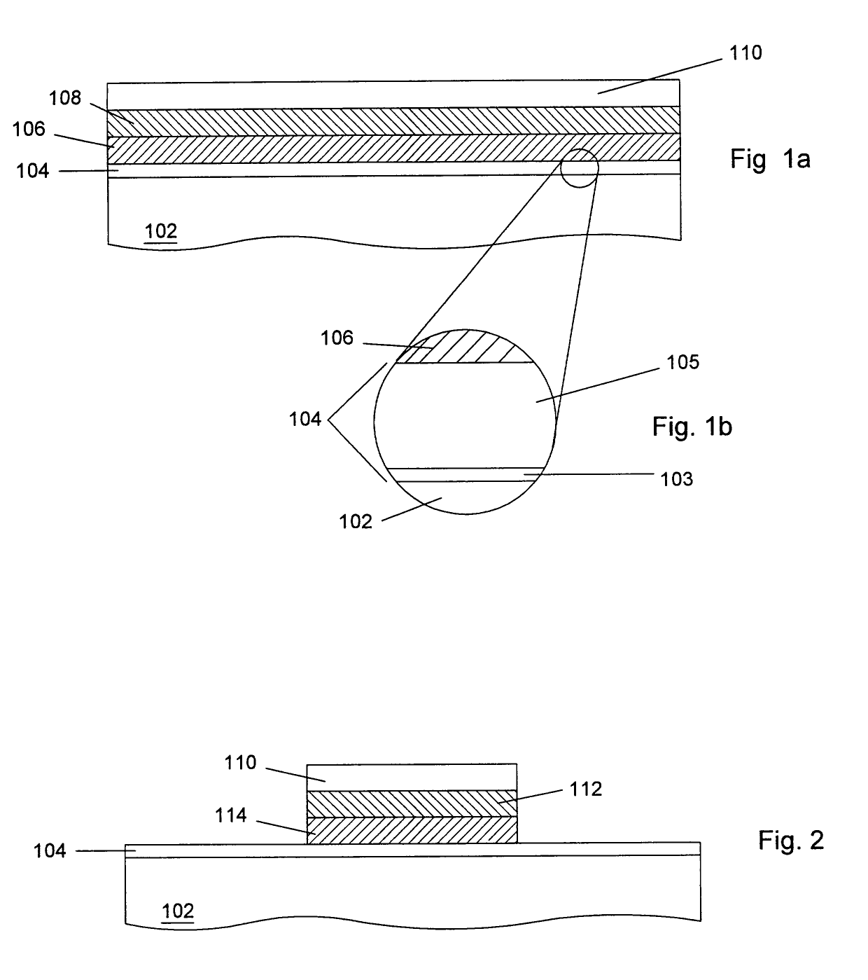

FIGS. 1-7 illustrate the formation of a transistor according to one embodiment of the present invention. Turning to FIG. 1, a semiconductor substrate 102, preferably composed of single crystalline silicon, is depicted, upon which a gate dielectric 104 is formed. Substrate 102 is slightly doped with p-type or n-type dopant species. In an alternate embodiment, p-type or n-type wells may be arranged within select regions of substrate 102 to allow for the formation of a CMOS integrated circuit which includes both NMOSFET and PMOSFET transistors. Although not shown in the depicted cross-section of substrate 102, dielectric isolation regions, such as trench isolation structures, may be arranged spaced distances apart within the substrate for dielectrically isolating the ensuing active areas.

Deposited entirely across substrate 102 is a barrier layer 104, depicted in FIG. 1a. Barrier layer 104 may be formed from thermally grown silicon oxide, silicon oxynitride or silicon nitride. Barrier layer 104 preferably acts as an buffer to prevent silicidation of regions of semiconductor substrate 100 beneath a subsequently formed gate dielectric. Preferably, barrier layer 104 is composed of a silicon oxynitride layer 103 and a silicon nitride layer 105, as depicted in FIG. 1b. Silicon oxynitride layer 103 may be either deposited or grown. Preferably, silicon oxynitride layer 103 is grown by treating the substrate 102 in an oxidation chamber with nitric oxide (NO) and/or nitrous oxide (N₂O) at a temperature of between about 600° C. to about 1100° C. Ammonia gas (NH₃) may be added to adjust the oxygen to nitrogen ratio of the silicon oxynitride layer. The silicon oxynitride layer is preferably grown to a thickness of up to about 1 angstrom.

After formation of silicon oxynitride layer 103, a silicon nitride layer 105 may be formed over the silicon oxynitride layer. Silicon nitride layer 105 may be formed using remote plasma deposition, in which a source of nitrogen (e.g., nitrogen or ammonia gas) is introduced into an energy source. The energy source may produce, for example, microwave radiation, radio frequency radiation, or ultraviolet radiation. Energy supplied by the radiation may cause the nitrogen source to dissociate into its constituent atoms. Nitrogen atoms may then be selectively carried to the surface of a semiconductor wafer by an inert gas such as helium. A gas mixture of a source of silicon (e.g., silane or dichlorosilane) may then be introduced into the process chamber. The nitrogen and the silicon-containing molecule react to produce silicon nitride, which then deposits onto the surface of the wafer. Preferably, the barrier layer of silicon nitride is between about 3-15 angstroms thick. The remote plasma and the supplied energy in combination allow the deposition rate of silicon nitride to be raised to an acceptable level. Silicon oxynitride layer 105 may be etched back such that the silicon oxynitride/silicon nitride stack (103/105) may have a combined thickness between about 3 to 10 angstroms. When a silicon oxynitride/silicon nitride stack, as depicted in FIG. 1B, is used, the silicon oxynitride layer 103 serves as a “pad oxide” to reduce inherent stresses that exist between CVD nitride on a silicon substrate.

After formation of dielectric layer 104, a transition metal spacer layer 106 is deposited upon the dielectric layer 104. Transition metal spacer layer 106 may be composed of titanium, zirconium, or tantalum. Transition metal spacer layer 106 is preferably deposited using a chemical vapor deposition process. Preferably, transition metal spacer layer 106 is deposited to a depth of between about 50 to about 200 angstroms.

Deposited upon transition metal layer 106 is a gate conductor layer 108. Gate conductor layer 108 is preferably composed of polysilicon, cobalt, or tungsten. Gate conductor layer 108 is preferably deposited using a chemical vapor deposition process (e.g., a plasma enhanced chemical vapor deposition (“PECVD”) process). When polysilicon is used as the gate conductor material, the polysilicon may be rendered conductive by implanting impurities into the polysilicon during or after polysilicon deposition. The upper surface of gate conductor layer 108 may be polished to substantially reduce its surface roughness. This polishing may be accomplished by mechanical polishing, chemical-mechanical polishing, or sacrificial etchback.

A masking layer 110 is preferably deposited upon gate conductor layer 108. Masking layer 110 may be composed of silicon oxide, silicon oxynitride, silicon nitride, photoresist material, or any other material that is dissimilar from gate conductor layer 108 and transition metal layer 106. Preferably, masking layer 110 is composed of photoresist material.

FIG. 2 illustrates the formation of a gate structure. Masking layer 110 is selectively patterned and removed from above portions adjacent to the gate conductor 112. Portions of gate conductive layer 108 and underlying portions of transition metal layer 106 not masked by the remaining masking layer may be removed by using, e.g., an anisotropic dry plasma etch to form gate conductor 112 overlying transition metal spacer 114. Barrier layer 104 may be retained upon semiconductor substrate 102 during the etch step.

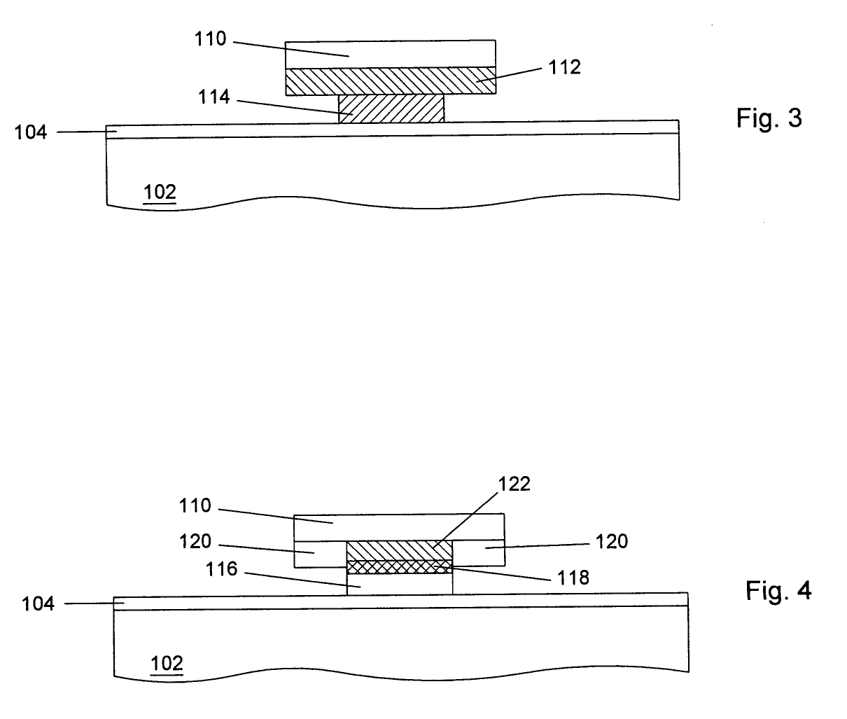

FIG. 3 illustrates a processing step in which a lateral width of transition metal spacer 114 is preferably reduced. The transition metal spacer 114 is preferably subjected to a wet etch. For example, if transition metal spacer 114 is composed of titanium, the lateral extent of spacer 114 may be reduced by treatment with a water/hydrogen peroxide/ammonium hydroxide (5:1:1) mixture for a short period of time. In this manner, the lateral extent of transition metal spacer 114 may be reduced. The etch is terminated after a select lateral amount of transition metal spacer 114 is removed.

FIG. 4 depicts the oxidation of transition metal spacer 114. Oxidation of transition metal spacer 114 converts substantially all of the transition metal spacer 114 to a transition metal oxide spacer 116. Oxidation is performed when transition metal spacer 114 is heated in a oxygen (O₂), nitric oxide (NO) or nitrous oxide (N₂O) atmosphere. The heating process may be performed in an annealing furnace or a Rapid Thermal Anneal (“RTA”) chamber. As a result of being subjected to a heat cycle in an oxygen containing atmosphere, transition metal spacer 114 is oxidized to form a transition metal oxide spacer 116. For example, if transition metal spacer 114 is composed of titanium, the oxidation of the spacer 114 converts the titanium into titanium dioxide (TiO₂). Similarly, a tantalum spacer is converted to tantalum pentoxide (Ta₂O₅) and a zirconium spacer is converted to zirconium oxide (ZrO₂).

Conversion of the transition metal spacer to a transition metal oxide spacer creates a high K material interposed between the gate conductor structure 112/118 and substrate 102. Titanium dioxide, tantalum pentoxide, and zirconium dioxide are all high K materials having a K value significantly greater than silicon dioxide. Thus, the distance between the gate conductor structure and the substrate may be increased without effecting the gate-to-substrate capacitance. By increasing this distance, the probability that the gate dielectric will break down is significantly reduced.

During oxidation of transition metal spacer 114, a portion of the transition metal spacer may react with the gate conductor 112 to form a silicide layer 1118. When the gate conductor is composed of polysilicon, the high temperatures required for oxidation of the transition metal spacer may cause formation of silicide layer 118 between gate conductor 112 and transition metal oxide spacer 116. Silicide layer 118, in combination with polysilicon gate conductor 112, together serve as the gate conductor structure. When the gate conductor 112 is composed of cobalt or tungsten, no silicide is formed. The gate conductor structure, in this case, would consist of the unoxidized portions of gate conductor 112.

Additionally, oxidation of the transition metal spacer may also cause exposed portions of gate conductor 112 to become partially oxidized, when the gate conductor is composed of polysilicon. Outer portions 120 may be converted to silicon dioxide or silicon oxynitride during the oxidation process, depending on the conditions used. The central portion of gate conductor 112 preferably remains unoxidized, (i.e., is composed of polysilicon). The oxidation of the gate conductor 112 causes a reduction in the lateral width of the gate conductor. Masking layer 110 preferably prevents the oxidation of an upper portion of the gate conductor. Thus, the height of the unoxidized portion of gate conductor 112 remains substantially unchanged.

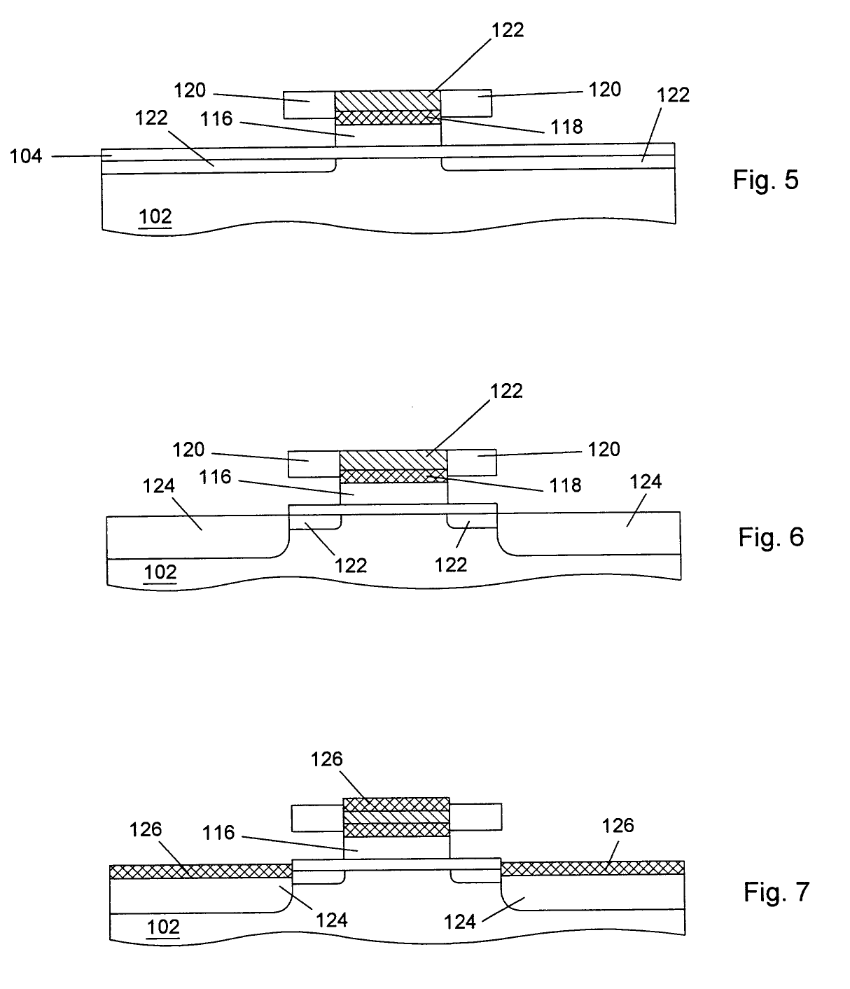

Subsequently, as shown in FIG. 5, a first dopant distribution is implanted into substrate 102. If a PMOSFET transistor is being fabricated, p-type dopant species are implanted; if an NMOSFET transistor is being fabricated, n-type dopant species are implanted. After removal of masking layer 110, substrate 102 is treated with a gaseous dopant source to form LDD areas 122. Transition metal spacer 116 and gate conductor 118/112 serve to mask the implant from the channel region. A variety of gaseous sources may be used to form LDD areas 122. For arsenic implantation, either arsine (AsH₃) or arsenic trifluoride (AsF₃) are used. Phosphorus gas sources may include either phosphine (PH₃) or phosphorus pentafluoride (PF₅). Boron gas sources may include either boron tri fluoride (BF₃), boron trichloride (BCl₃), or diborane (B₂H₆). The use of a gaseous dopant species rather than an ion implantation process allows the implantation to enter portions of substrate 102 directly under oxidized gate conductor portions 120. The gate structure 112/118 and transition metal oxide spacer 116 serve to align LDD implant 122 adjacent to the transition metal oxide spacer.

FIG. 6 illustrates an implantation of a second dopant distribution into source/drain regions of substrate 102. Portions of barrier layer 104 which are not directly under oxidized gate conductor portions 120 are preferably removed by a dry etch process, e.g., a plasma etch. The process conditions are chosen such that the silicon nitride layer is removed with high selectivity against removal of the underlying silicon oxynitride layer (see FIG. 1b). A plasma etch process using a NF₃ plasma is preferred. The silicon oxynitride layer serves to protect substrate 102 from the plasma etch process. Removal of the underlying silicon oxynitride layer is preferably performed using a dry etch process under conditions which remove the silicon oxynitride layer with a high selectivity toward substrate 102. A source/drain implant is preferably forwarded into the substrate using an ion implantation process. By using ion implantation, the oxidized gate conductor portions 120 preferably mask the implantation from reaching substrate 102 under these structures, as well as reaching the channel region under transition metal spacer. Source/drain implant 124 is of the same dopant species as the first implant 122, albeit at a higher concentration and energy than the first dopant implant.

Alternatively, LDD areas 122 and source/drain regions 124 may be simultaneously formed by an ion implantation step. Referring back to FIG. 4, masking layer 110 may be removed as described above. A high energy ion implantation may now be performed to concurrently form LDD areas 122 and source drain regions 124. As the ions move toward the semiconductor substrate they may be hindered from reaching the semiconductor substrate by gate conductor structure 122/118, gate dielectric 116, and oxidized portions 120. The gate conductor structure 122/118 and gate dielectric 116 both inhibit the implantation of ions into the channel region. The high energy of implantation, however, may be sufficient to pass through the oxidized portions 120 to form the LDD areas 122. The portions of semiconductor substrate 102 which are not directly under gate dielectric 116 or oxidized portions 120 receive a higher implant concentration than the LDD areas 122. In this manner source/drain regions 124 may be formed during formation of the LDD areas 122.

FIG. 7 depicts the formation of self-aligned silicide (i.e., salicide) structures 126 on the gate conductor structure and the source/drain regions. A refractory metal (e.g., titanium or cobalt) is deposited across the semiconductor topography using either sputter deposition from a metal target or metal organic chemical vapor deposition (“MOCVD”) from a gas comprising a metal organic-containing compound. The refractory metal is preferably exposed to a form of radiation supplied from either an annealing furnace or a Rapid Thermal Anneal (“RTA”) chamber. As a result of being subjected to a heat cycle, the refractory metal reacts with underlying silicon of substrate 102 and polysilicon gate conductor 112 to form metal suicides 126. Unreacted portions of the refractory metal are then removed using an etch technique which is highly selective to the metal. Consequently, self-aligned silicide (i.e., salicide) structures 126 are formed exclusively upon source/drain regions 124 and the upper surface of gate conductor 112. The presence of oxidized gate conductor portions 120 inhibits silicide from forming upon sidewall surfaces of gate conductor 112.

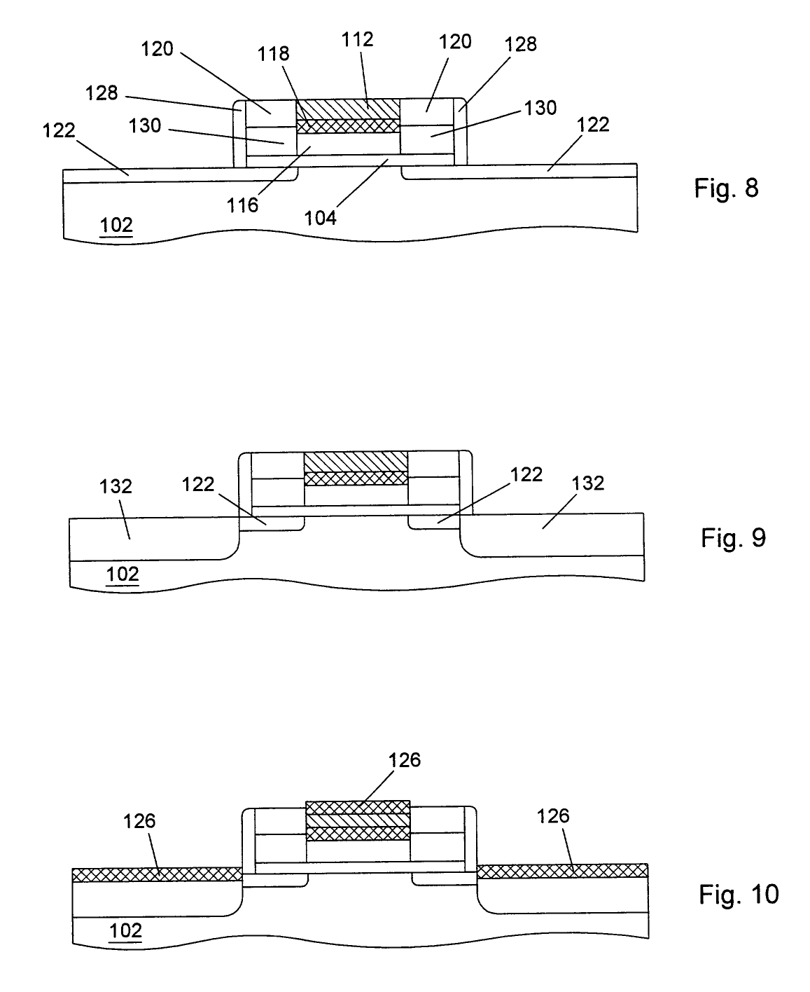

FIGS. 8-10 demonstrate the formation of a transistor according to another embodiment of the present invention. An intermediate structure, depicted in FIG. 8, includes barrier layer 104, transition metal spacer 116, gate conductor structure 112/118, oxidized portions 120, and LDD areas 122. The intermediate structure is preferably formed according to the processing steps described above in FIGS. 1-5. After removal of the exposed portions of barrier layer 104, as described above for FIG. 6, a pair of spacer structures 128 are formed on side walls of oxidized portions 120. A spacer material is deposited from a CVD apparatus across the entire substrate to form a conformal layer. Spacer material may be formed from silicon dioxide, silicon nitride, or silicon oxynitride. After deposition, the spacer material undergoes an anisotropic etch. Anisotropic etch is designed as a plasma etch employing both physical and chemical removal mechanisms. Ions are bombarded at an angle substantially perpendicular to substrate 102 upper surface. This causes substantially horizontal surfaces to be removed faster than substantially vertical surfaces. Accordingly, anisotropic etching removes a portion of the spacer material existing over horizontal surfaces. In this manner, spacer structures 128 are formed in those regions near substantially vertical surfaces (i.e., regions adjacent oxidized portions 120). Spacer structures 128 are preferably form a bridge between oxidized portions 120 and sidewall surfaces of barrier layer 104. Bridging of the spacer structures 128 in this manner creates voids 130 defined by transition metal oxide spacer 116, oxidized portions 120, and spacer structures 130. The void may contain gases used during the conformal deposition of the spacer material.

FIG. 9 illustrates an implantation of a second dopant distribution into source/drain regions of substrate 102. Source and drain implant areas 120 may be formed by implanting dopant ions substantially perpendicular to the surface of semiconductor substrate 102. Preferably, the second dopant implant is performed at a higher concentration and a higher energy than the first dopant implant. Spacer structures 128 together with oxidized portions 120 preferably serve to mask the lightly doped drain regions of semiconductor substrate 100 such that substantially no ions from source/drain implant are implanted into the lightly doped drain areas 122.

FIG. 10 depicts the formation of self-aligned silicide (i.e., salicide) structures 126 on the gate conductor structure and the source/drain regions in a manner as described above in FIG. 7. The spacer structures 128 preferably inhibit the deposition of metal under oxidized portions 120.

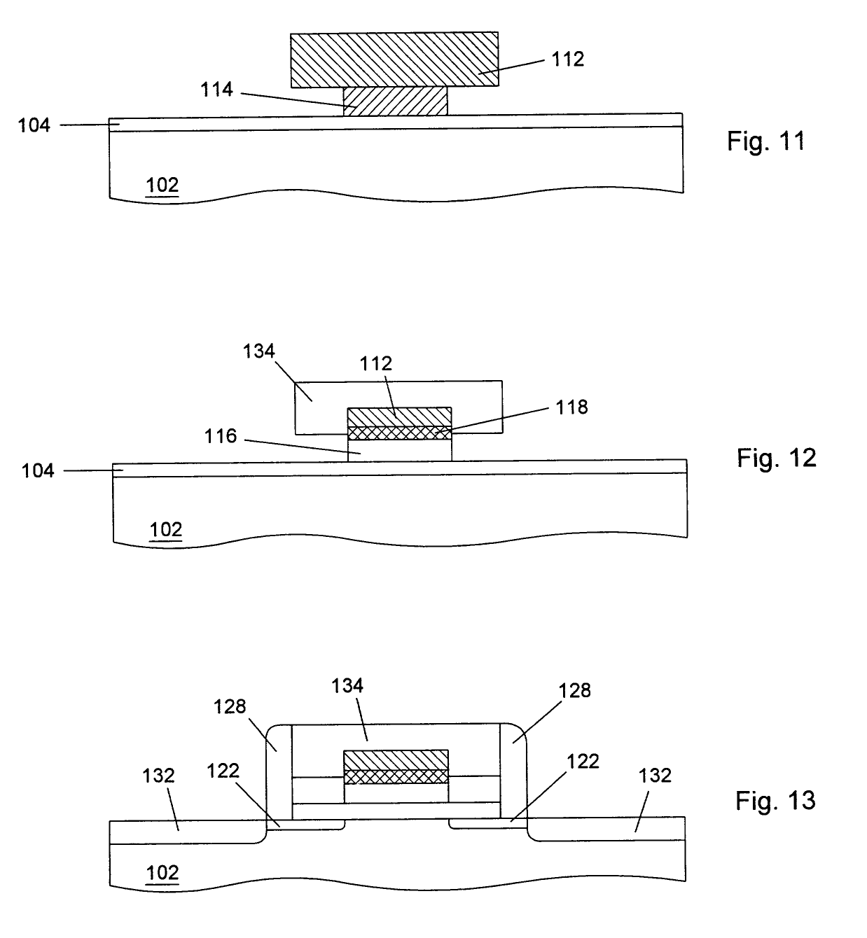

FIGS. 11-13 demonstrate the formation of a transistor according to another embodiment of the present invention. An intermediate structure, depicted in FIG. 11, includes a barrier layer 104, a transition metal spacer 114, and a gate conductor 112. The intermediate structure is preferably formed according to the processing steps of FIGS. 1-3. Masking layer 110 (shown in FIG. 3) has been removed. The formation of gate conductor 112 is preferably performed such that gate conductor 112 has a width substantially greater than a width of the gate conductor formed in the previous embodiments. Gate conductor 112 may have a height substantially greater than a height of transition metal spacer 114.

FIG. 12 depicts the oxidation of transition metal spacer 114. Oxidation of transition metal spacer 114 converts substantially all of the transition metal spacer 114 to a transition metal oxide spacer 116 as described previously. Conversion of the transition metal spacer to a transition metal oxide spacer creates a high K material interposed between the gate conductor structure 112/118 and substrate 102.

During oxidation of transition metal spacer 114, a portion of the transition metal spacer may react with the gate conductor 112 to form a silicide layer 118. When the gate conductor is composed of polysilicon, the high temperatures required for oxidation of the transition metal spacer may cause formation of silicide layer 118 between gate conductor 112 and transition metal oxide spacer 116. Silicide layer 118, in combination with polysilicon gate conductor 112, together serve as the gate conductor structure. When the gate conductor 112 is composed of cobalt or tungsten, no silicide is formed. The gate conductor structure, in this case, would consist of the unoxidized portions of gate conductor 112.

Additionally, oxidation of the transition metal spacer may also cause exposed portions of gate conductor 112 to become partially oxidized when the gate conductor is composed of polysilicon. Outer portion 134 may be converted to silicon dioxide or silicon oxynitride during the oxidation process, depending on the conditions used. The central portion of gate conductor 112 preferably remains unoxidized, (i.e., is composed of polysilicon). The oxidation of the gate conductor 112 causes a reduction in the lateral width of the gate conductor. Typically, the oxidation of the transition metal spacer occurs at a substantially faster rate than the oxidation of the gate conductor. To ensure that the oxidation of the transition metal spacer may be substantially completed before the gate conductor is oxidized, the gate conductor is preferably formed having a height sufficient to inhibit complete oxidation of the gate conductor during the time period required to oxidize the transition metal spacer. Thus, oxidation of the gate conductor forms a layer of dielectric material surrounding the gate conductor along the sidewalls and the upper surface of the gate conductor. An advantage of this process is that the formation of an interlevel dielectric by an additional processing step may be avoided.

FIG. 13 depicts the formation of spacer structures 128, LDD areas 122, and source/drain regions 132. These regions are preferably formed according to the processing steps described in FIGS. 8 and 9.

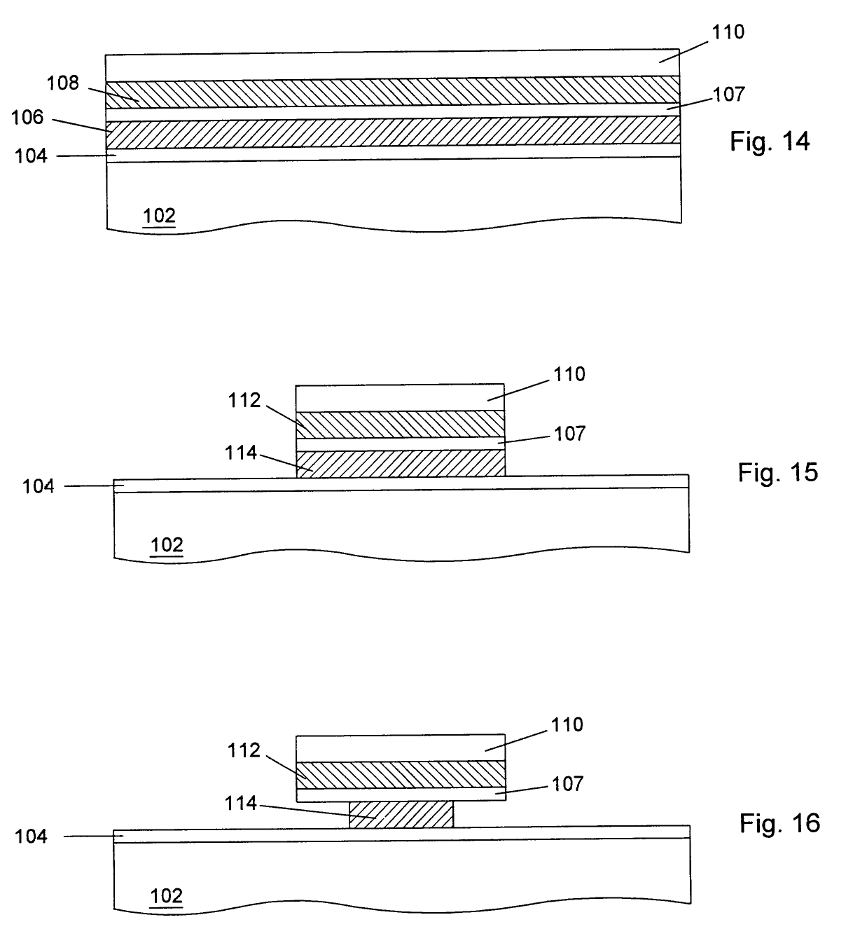

FIGS. 14-19 demonstrate the formation of a transistor according to another embodiment of the present invention. An intermediate structure, depicted in FIG. 14, includes a first barrier layer 104, a transition metal layer 106, a gate conductor layer 108 and a masking layer 110. The intermediate structure is preferably formed according to the processing steps described in FIG. 1. In addition to these layers, a second barrier layer 107 is formed between the gate conductor layer 108 and transition metal layer 106. Second barrier layer 107 is preferably formed of CVD deposited silicon nitride. Second barrier layer 107 may, alternatively, be composed of a lower silicon nitride layer and an upper silicon oxynitride layer. Upper silicon oxynitride layer serves as a “pad oxide” to reduce inherent stresses that exist between CVD nitride and the gate conductor 112, when the gate conductor is composed of polysilicon.

FIGS. 15 and 16 depict processing steps similar to those described in FIGS. 2 and 3, where the layers overlying the semiconductor substrate are etched to form a gate structure. After etching, the lateral extent of the transition metal spacer 114 is preferably reduced by use of a wet etch process.

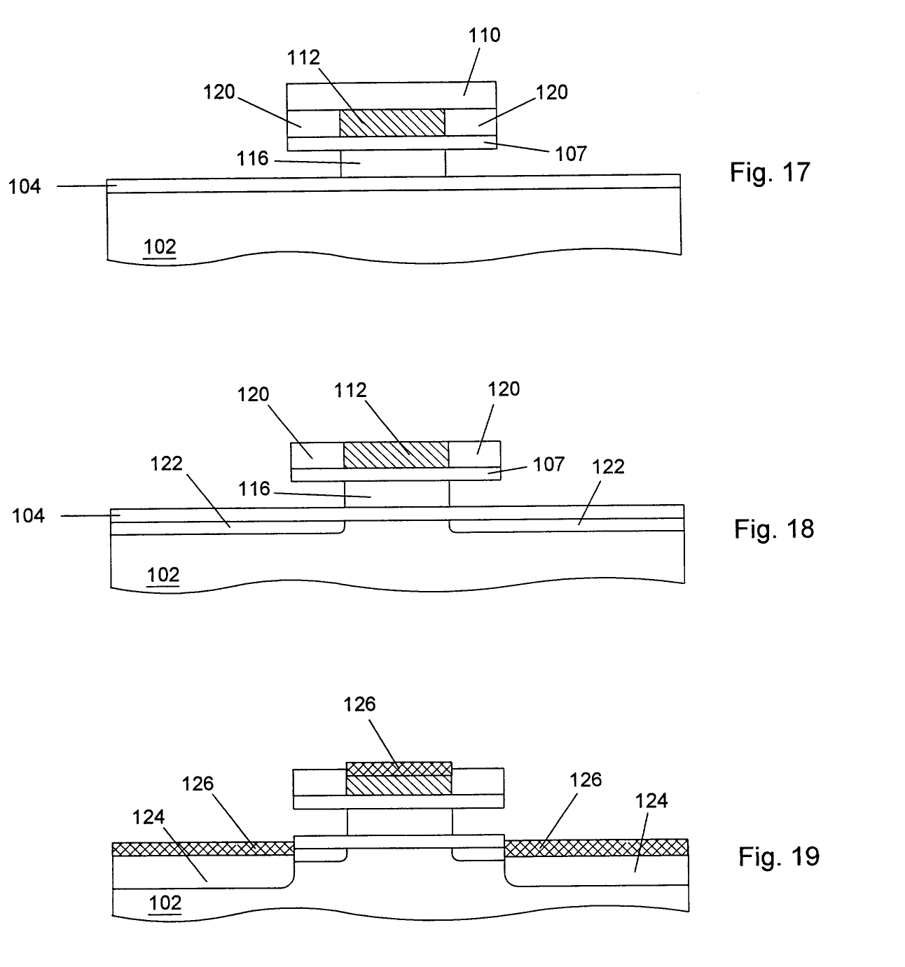

FIG. 17 depicts the oxidation of transition metal spacer 114. Oxidation of transition metal spacer 114 converts substantially all of the transition metal spacer 114 to a transition metal oxide spacer 116 as described previously. Conversion of the transition metal spacer to a transition metal oxide spacer creates a high K material interposed between the gate conductor structure 112/118 and substrate 102.

In the previous embodiments, oxidation of transition metal spacer 114 causes a portion of the transition metal spacer to react with the gate conductor 112 to form a silicide layer 118 (see FIG. 4). In the current embodiment, the second barrier layer preferably inhibits the formation of a silicide layer between the transition metal oxide spacer and the gate conductor.

Additionally, oxidation of the transition metal spacer may also cause exposed portions of gate conductor 112 to become partially oxidized, when the gate conductor is composed of polysilicon. Outer portions 120 may be converted to silicon dioxide or silicon oxynitride during the oxidation process, depending on the conditions used. The central portion of gate conductor 112 preferably remains unoxidized, (i.e., is composed of polysilicon). The oxidation of the gate conductor 112 causes a reduction in the lateral width of the gate conductor. Masking layer 110 preferably prevents the oxidation of an upper portion of the gate conductor. Thus, the height of the unoxidized portion of gate conductor 112 remains substantially unchanged.

Subsequently, as shown in FIG. 18, a first dopant distribution is implanted into substrate 102. If a PMOSFET transistor is being fabricated, p-type dopant species are implanted; if an NMOSFET transistor is being fabricated, n-type dopant species are implanted. After removal of masking layer 110, substrate 102 is treated with a gaseous dopant source to form LDD areas 122. Transition metal spacer 116 and gate conductor 112 serve to mask the implant from channel the region. A variety of gaseous sources may be used to form LDD areas 122, as described above. The use of a gaseous dopant species, rather than an ion implantation process, allows the implantation to enter portions of substrate 102 directly under oxidized gate conductor portions 120. The gate structure 112 and transition metal oxide spacer 116 serves to align LDD implant 122 adjacent to gate the transition metal oxide spacer.

FIG. 19 depicts the formation of source/drain regions 132 and silicide regions 126. These regions are preferably formed in a manner similar to the processing steps described in FIGS. 6 and 7.

It will be appreciated to those skilled in the art having the benefit of this disclosure that the invention is capable of applications with numerous types of MOS-processed circuits. Furthermore, it is to be understood that the form of the invention shown and described is to be taken as presently preferred embodiments. Various modifications and changes may be made to each and every processing step as would be obvious to a person skilled in the art having the benefit of this disclosure. It is intended that the following claims be interpreted to embrace all such modifications and changes and, accordingly the specification and drawings are to be regarded in an illustrative rather than a restrictive sense.

What is claimed is:

1. A method for forming an integrated circuit, comprising:
patterning a gate conductor spaced above a semiconductor substrate by a transition metal spacer;
reducing a lateral extent of the transition metal spacer to a length less than a lateral extent of the gate conductor; and
oxidizing the transition metal spacer to form a transition metal oxide spacer.

2. The method of claim 1, wherein the lateral length of the transition metal spacer is reduced below a lateral length obtainable by a photolithographic process.

3. The method of claim 1, wherein the lateral length of the transition metal spacer is reduced by an isotropic etch.

4. The method of claim 1, further comprising masking the gate conductor prior to oxidizing the transition metal spacer.

5. The method of claim 1, wherein the gate conductor has a height substantially greater than a height of the transition metal spacer.

6. The method of claim 5, wherein oxidizing the transition metal spacer concurrently oxidizes a lateral perimeter of the gate conductor.

7. The method of claim 1, further comprising forming a first barrier layer between the transition metal spacer and the semiconductor substrate.

8. The method of claim 1, further comprising:
forming a first barrier layer between the transition metal spacer and the semiconductor substrate; and
forming a second barrier layer between the transition metal spacer and the gate conductor.

9. The method of claim 1, further comprising implanting a first dopant distribution into the semiconductor substrate substantially aligned with sidewalls of the transition metal spacer.

10. The method of claim 9, wherein implanting a first dopant distribution comprises treating the semiconductor with gaseous arsenic.

11. The method of claim 9, further comprising:
forming spacer structures upon sidewalls of the gate conductor; and
implanting a second dopant distribution into a source region and a drain region.

12. The method of claim 11, further comprising forming silicide layers upon the gate conductor, the source region, and the drain region.

13. The method of claim 1, wherein the transition metal spacer is selected from the group consisting of titanium, zirconium, and tantalum.

14. The method of claim 1, wherein the gate conductor is selected from the group consisting of polysilicon, cobalt, or tungsten.

15. The method of claim 1, wherein oxidizing the transition metal spacer concurrently forms a metal silicide layer between the gate conductor and the transition metal oxide spacer.

16. The method of claim 1, further comprising a dopant distribution into the semiconductor substrate such that LDD areas are formed substantially aligned with sidewalls of the transition metal oxide spacer, and wherein source/drain regions are concurrently formed laterally spaced from the transition metal oxide spacer.

17. A transistor comprising:
a transition metal oxide spacer extending above a semiconductor substrate; and
a gate conductor arranged on the upper surface of the transition metal spacer, wherein a lateral length of the gate conductor is substantially greater than a lateral length of the transition metal spacer.

18. The transistor of claim 17, wherein the transition metal oxide spacer is selected from the group consisting of titanium oxide, tantalum oxide, and zirconium oxide.

19. The transistor of claim 17, further comprising a dielectric layer interposed between the semiconductor substrate and the transitional metal oxide spacer.

20. The transistor of claim 17, wherein the gate conductor comprises polysilicon.

21. The transistor of claim 17, wherein the gate conductor comprises polysilicon and metal silicide.

22. The transistor of claim 17, wherein an outer portion of the gate conductor comprises silicon dioxide and wherein an inner portion of the gate conductor comprises polysilicon.

23. The transistor of claim 17, further comprising spacer structures formed on sidewalls of the gate conductor, wherein a pair of voids are defined by the spacer structures, the gate conductor and the transition metal oxide spacer.

24. The transistor of claim 17, wherein the gate conductor is selected from the group consisting of polysilicon, cobalt and tungsten.

25. The transistor of claim 17, wherein side portions of the gate conductor comprise silicon oxide and wherein a middle portion of the gate conductor comprises polysilicon.

26. The transistor of claim 17, further comprising a dielectric layer interposed between the transition metal oxide spacer and the gate conductor.

27. A transistor comprising:
a transition metal oxide spacer extending above a semiconductor substrate;
a gate conductor arranged on the upper surface of the transition metal spacer, wherein a lateral length of the gate conductor is substantially greater than a lateral length of the transition metal spacer; and
a dielectric layer interposed between the transitional metal oxide spacer and the gate dielectric.

28. A transistor comprising:
a transition metal spacer extending above a semiconductor substrate; and
a gate conductor arranged on the upper surface of the transition metal spacer, wherein a lateral length of the gate conductor is substantially greater than a lateral length of the transition metal spacer.
